(19) United States
(12) Patent Application Publication
(10) Pub. No.: US 2026/0094761 A1
(43) Pub. Date: Apr. 2, 2026

(54) SYSTEMS AND METHODS FOR IMPLEMENTING AN AIR CORE INDUCTOR ARRAY

(71) Applicant: ATI Technologies ULC, Markham (CA)

(72) Inventor: Fei Guo, Markham (CA)

(73) Assignee: ATI Technologies ULC, Markham (CA)

(21) Appl. No.: 18/176,256

(22) Filed: Feb. 28, 2023

(51) Int. Cl. H01F 27/42; H01F 41/04; H01L 27/01

(52) U.S. Cl. CPC H01F 27/42; H01F 41/04; H10D 86/85

(57) ABSTRACT

The disclosed air core inductor array includes a top plate positioned in a first plane and a bottom plate positioned in a second plane. The disclosed air core inductor array additionally includes a plurality of air core inductors arranged between the top plate and the bottom plate, wherein the top plate and the bottom plate form a mutual inductor. Various other methods, systems, and computer-readable media are also disclosed.

### BACKGROUND

An Integrated Voltage Regulator (IVR) is a high-performance power management device designed to provide performance, efficiency, size, and cost benefits to energy-hungry, data-intensive, electronics applications. These benefits are realized by replacing the traditional power management integrated circuit (PMIC) solutions with a single tiny integrated circuit (IC).

### BRIEF DESCRIPTION OF THE DRAWINGS

The accompanying drawings illustrate a number of example embodiments and are a part of the specification. Together with the following description, these drawings demonstrate and explain various principles of the present disclosure.

FIG. 1 is a flow diagram of an example method for implementing an air core inductor array.

FIG. 2 is a rising view of an example air core inductor array including a mutual inductor implemented as an LC circuit.

FIG. 3 is a diagrammatic view of example LC circuits.

FIG. 4 is a graphical representation of analysis results relating to linear frequency exhibited by an air core inductor array including a mutual inductor implemented as an LC circuit.

FIG. 5 is a graphical representation of analysis results relating to linear frequency exhibited by an air core inductor array including a mutual inductor implemented as an LC circuit.

FIG. 6 is a top view of an example air core inductor array having a hexagonal structure and including a mutual inductor implemented as an LC circuit.

FIG. 7 is a graphical representation of analysis results relating to linear frequency exhibited by an air core inductor array having a hexagonal structure and including a mutual inductor implemented as an LC circuit.

FIG. 8 is a top view of an example air core inductor array having a hexagonal structure and an adjustable radius.

FIG. 9 is a rising view of an air core inductor array model depicting analysis results relating to magnetic field strength exhibited by an air core inductor array having a hexagonal structure and an adjustable radius.

FIG. 10 is a graphical representation of analysis results relating to voltage of an air core inductor array having a hexagonal structure and an adjustable radius.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to systems and methods for implementing an air core inductor array. In the semiconductor industry, integrated voltage regulators have become a major feature in high end application specific integrated circuits (ASICs). An option for the inductor implementation is to use the integrated circuit (IC) packaging structure to implement the inductor. However, previous studies demonstrate that, when using the packaging structure to implement the inductor, the induction value that is produced is limited due to resistance constraints. One way to improve the effective inductance is to use mutual inductance.

The disclosed air core inductor array and integrate voltage regulator can implement mutual inductance by employing one or more features. Example features include providing a mutual inductor to the air core inductor array, selecting radius of the air core inductor array to maximize benefit of the mutual inductor to effective inductance of the air core inductor array, using a tuning capacitor in a mutual inductor formed as an LC circuit, and/or implementing a hexagonal structure and die placement that saves space on a die and promotes further mutual inductance between adjacent air core inductor arrays. Any one or combination of these features can significantly improve the effective inductance of the air core inductor array and, thus, an integrated voltage regulator that includes such air core inductor arrays.

In one example, an air core inductor array includes a top plate positioned in a first plane, a bottom plate positioned in a second plane, and a plurality of air core inductors arranged between the top plate and the bottom plate, wherein the top plate and the bottom plate form a mutual inductor.

Another example can be the previously described air core inductor array, further including a center feed arranged as at least one plated through hole surrounded by the air core inductor array.

Another example can be any of the previously described air core inductor arrays, further including a via fence arranged as a plurality of plated through holes surrounding the air core inductor array, wherein the via fence and the center feed are shorted to at least one of the top plate or the bottom plate.

Another example can be any of the previously described air core inductor arrays, further including a tuning capacitor connected to the center feed and the via fence.

Another example can be any of the previously described air core inductor arrays, wherein the tuning capacitor is located on a same die on which the air core inductor array and the mutual inductor formed of the top plate, the bottom plate, the center feed, and the via fence are located.

Another example can be any of the previously described air core inductor arrays, further including a switch connected to tune an equivalent series resistance of the tuning capacitor.

Another example can be any of the previously described air core inductor arrays, wherein the tuning capacitor is located off of a die on which the air core inductor array and the mutual inductor formed of the top plate, the bottom plate, the center feed, and the via fence are located.

Another example can be any of the previously described air core inductor arrays, wherein a radius of the air core inductor array is selected to maximize a mutual inductance between the air core inductor array and the mutual inductor formed of the top plate, the bottom plate, the center feed, and the via fence.

Another example can be any of the previously described air core inductor arrays, wherein the plurality of air core inductors is arranged in a hexagonal structure.

In one example, an integrated voltage regulator can include an air core inductor array, a mutual inductor arranged as a top plate positioned above the air core inductor array, a bottom plate positioned below the air core inductor array, a via fence including a plurality of plated through holes surrounding the air core inductor array, and a center feed arranged as at least one plated through hole surrounded by the air core inductor array, wherein the via fence and the center feed are shorted to at least one of the top plate or the bottom plate, and a tuning capacitor connected to the center feed and the via fence.

Another example can be the previously described integrated voltage regulator, wherein the air core inductor array includes a plurality of air core inductors arranged in a hexagonal structure.

Another example can be any of the previously described integrated voltage regulators, wherein a radius of the air core inductor array is selected to maximize a mutual inductance between the air core inductor array and the mutual inductor.

Another example can be any of the previously described integrated voltage regulators, wherein the tuning capacitor is located on a same die on which the air core inductor array and the mutual inductor.

Another example can be any of the previously described integrated voltage regulators, further including a switch connected to tune an equivalent series resistance of the tuning capacitor.

Another example can be any of the previously described integrated voltage regulators, wherein the tuning capacitor is located off of a die on which the air core inductor array and the mutual inductor are located.

In one example, a method can include determining a radius of an air core inductor array including a plurality of air core inductors, wherein a radius of the air core inductor array is determined to maximize a mutual inductance between the air core inductor array and a mutual inductor, dividing the air core inductor array into a plurality of segments that each form an air core inductor of the air core inductor array, and adding a top plate and a bottom plate respectively above and below the plurality of air core inductors in a manner that forms a mutual inductor.

Another example can be the previously described methods, further including forming a center feed of the air core inductor array by providing at least one plated through hole surrounded by the air core inductor array, wherein the center feed is shorted to at least one of the top plate or the bottom plate.

Another example can be any of the previously described methods, further including forming a via fence by providing a plurality of plated through holes surrounding the air core inductor array, wherein the via fence is shorted to at least one of the top plate or the bottom plate.

Another example can be any of the previously described methods, further including connecting a tuning capacitor to the center feed and the via fence.

Another example can be any of the previously described methods, wherein the plurality of air core inductors is arranged in a hexagonal structure.

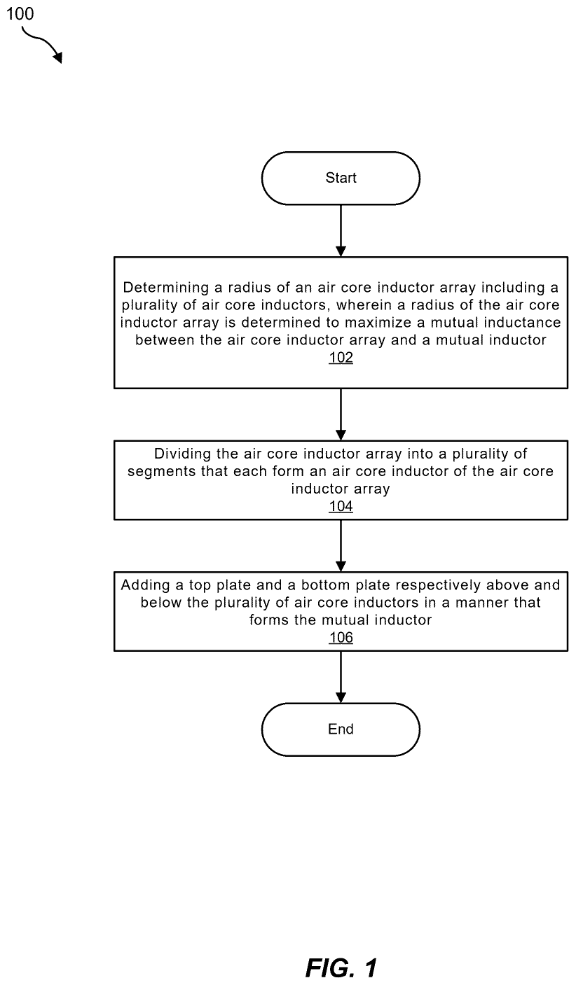

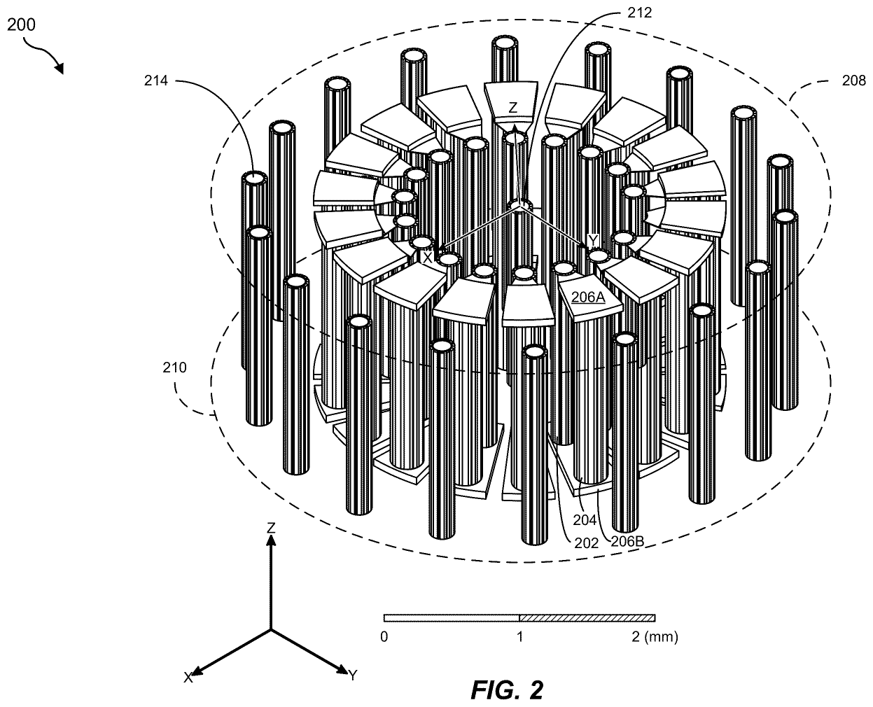

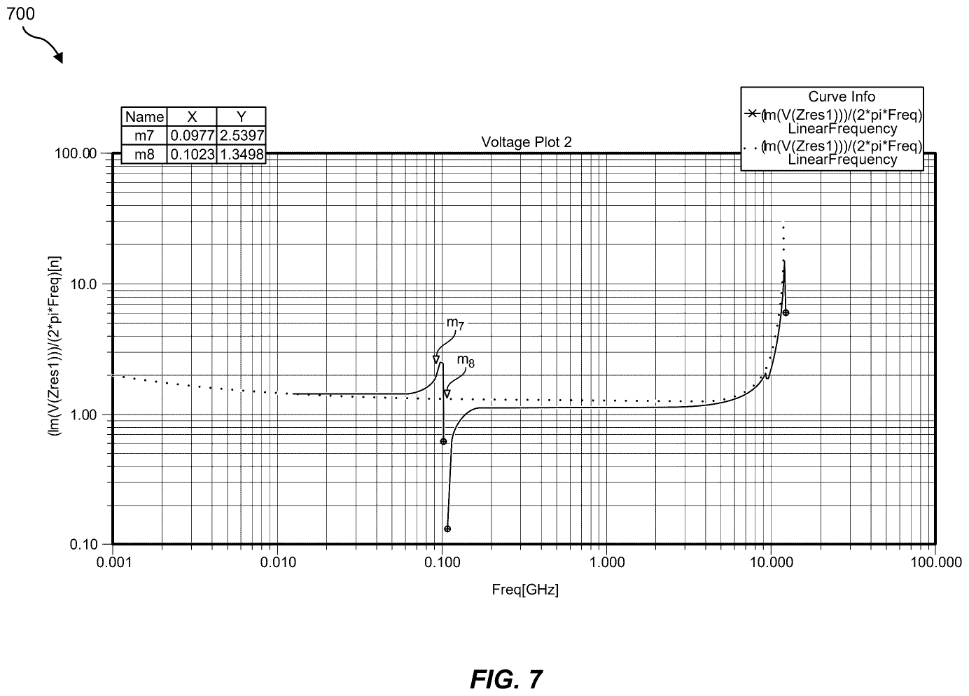

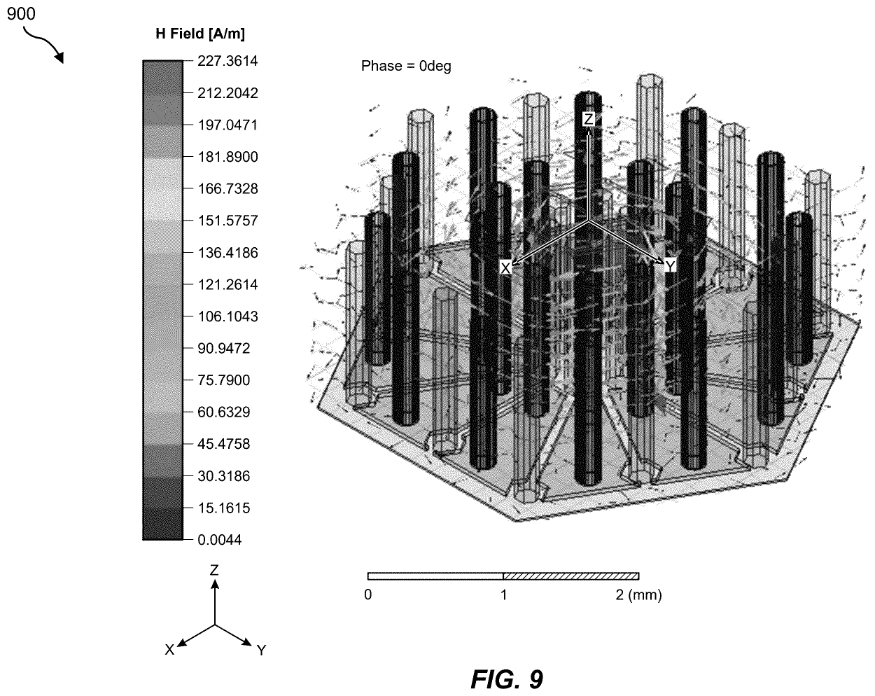

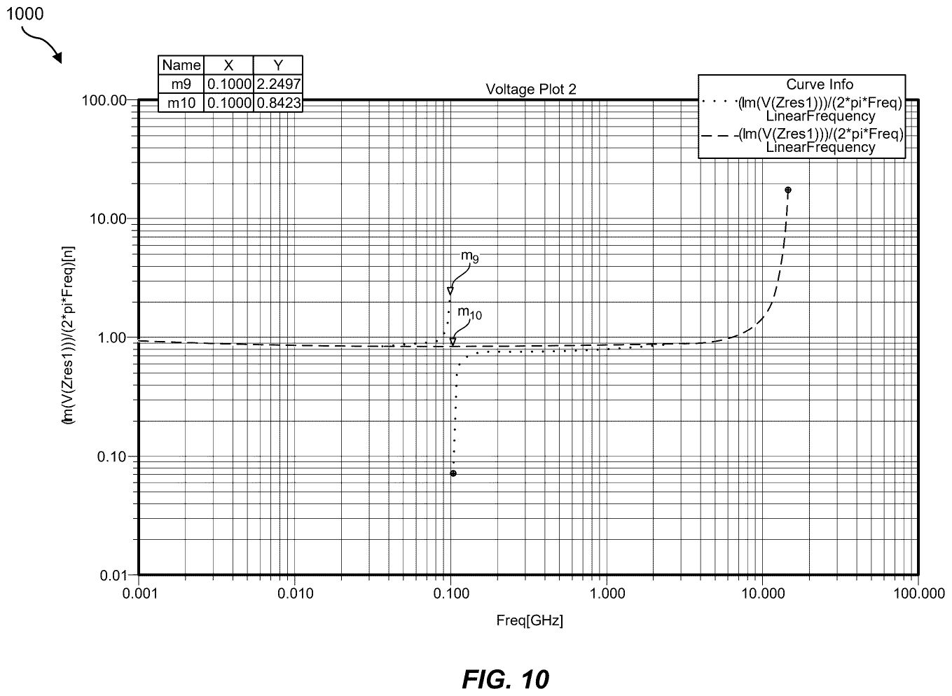

The following will provide, with reference to FIG. 1, detailed descriptions of example methods for implementing an air core inductor array and/or an integrated voltage regulator. Detailed descriptions of example air core inductor arrays and/or integrated voltage regulators having mutual inductors will also be provided in connection with FIGS. 2-6. In addition, detailed descriptions of example air core inductor arrays and/or integrated voltage regulators having hexagonal structures will be provided in connection with FIGS. 7-12.

FIG. 1 is a flow diagram of an example method 100 for implementing an air core inductor array. The steps shown in FIG. 1 can be performed with the aid of any suitable computer-executable code and/or computing system. In one example, each of the steps shown in FIG. 1 can be represented by multiple sub-steps, examples of which will be provided in greater detail below.

As illustrated in FIG. 1, step 102 can include determining a radius of an air core inductor array. For example, step 102 can include determining a radius of an air core inductor array including a plurality of air core inductors, wherein a radius of the air core inductor array is determined to maximize a mutual inductance between the air core inductor array and a mutual inductor.

The term “air core inductor array,” as used herein, can generally refer to an array of inductors that do not depend on a ferromagnetic material to achieve a specified inductance. For example, and without limitation, air core inductor arrays can include coils that can be produced with copper material, insulated wire, stripped and non-stripped ends, and tinned or bare ends. In some examples, the air core inductor array can be implemented in an integrated voltage regulator of an application specific integrated circuit (ASIC). An integrated voltage regulator can correspond to a high-performance power management device designed to provide performance, efficiency, size, and cost benefits to energy-hungry, data-intensive, electronics applications by replacing the traditional power management integrated circuit (PMIC) solutions with a single tiny integrated circuit. The integrated voltage regulator can create and maintain a fixed output voltage, irrespective of changes to the input voltage or load conditions. Thus, the integrated voltage regulator can keep voltages from a power supply within a range that is compatible with other electrical components.

The term “mutual inductance,” as used herein, can generally refer to a ratio between an electromagnetic field induced in one loop or coil by a rate of change of current in another loop or coil. In this context, a “mutual inductor” can be accomplished by bringing two coils in proximity with one another so that magnetic fields in the coils tend to link with one another. This property of a coil, which affects or changes the current and voltage in another coil, is called mutual inductance.

Step 102 can be performed in various ways. For example, there are three factors that can impact the effective air core inductor array (ACI) inductance: the radius of the ACI array; the distance between ground plated through holes (PTHs); and the distance between ACI PTHs. In some examples, iterative optimization across multiple parameters can be performed to achieve the best results. In some examples, the distance between ground PTHs (e.g., on the periphery) and ACI PTHs can be minimized based on manufacturer capability. In performing the analyses, a simulation of an air core inductor array circuit and/or an integrated voltage regulator circuit can vary one or more of these parameters and identify a maximum mutual inductance. In some examples, user inputs can trigger definition and/or variation of one or more parameters. Alternatively or additionally, one or more electrical characteristics of the circuit or circuits (e.g., voltage plot) can be produced and/or displayed to aid in identifying a set of one or more parameters that maximizes the mutual inductance. In some examples, the plurality of air core inductors can be arranged in a hexagonal structure. In other examples, the air core inductor array can have a circular or other polygonal shape.

Step 104 can include dividing the air core inductor array. For example, step 104 can include dividing the air core inductor array into a plurality of segments that each form an air core inductor of the air core inductor array.

Step 104 can be performed in various ways. For example, step 104 can include dividing a hexagonal structure into twelve segments that each form an air core inductor of the air core inductor array. In other examples, step 104 can include dividing the hexagonal structure into a number of segments that is an integer multiple of twelve (e.g., twenty-four, thirty-six, forty-eight, etc.).

Step 106 can include adding a top plate and a bottom plate. For example, step 106 can include adding a top plate and a bottom plate respectively above and below the plurality of air core inductors in a manner that forms the mutual inductor.

The term “plate,” as used herein, can generally refer to electrically conductive material formed in a plane. In this context, a “top plate” and a “bottom plate” can reside in parallel planes that respectively are located above and below the plurality of air core inductors. In some examples, the top plate and the bottom plate can electrically connect to opposite ends of the air core inductors.

Step 106 can be performed in various ways. For example, step 106 can include forming a center feed of the air core inductor array by providing at least one plated through hole surrounded by the air core inductor array, wherein the center feed is shorted to at least one of the top plate or the bottom plate. For example, one end of the center feed can be shorted to one of the top plate or the bottom plate and be open at an opposite end. Alternatively or additionally, step 106 can include forming a via fence by providing a plurality of plated through holes surrounding the air core inductor array, wherein the via fence is shorted to at least one of the top plate or the bottom plate. For example, opposite ends of the via fence can be shorted to both the top plate and bottom plate. Alternatively or additionally, step 106 can include connecting a tuning capacitor to the center feed and the via fence. For example, the tuning capacitor can be connected to an open end of the center feed and to the one of the plates (e.g., top plate or bottom plate) to which the center feed is not shorted. Alternatively or additionally, step 106 can include locating the tuning capacitor on a same die on which the air core inductor array and a mutual inductor formed of the center feed and the via fence are located. Alternatively or additionally, step 106 can include connecting the tuning capacitor to a switch connected to tune an equivalent series resistance of the tuning capacitor. In other examples, the tuning capacitor can be located off of a die on which the air core inductor array and the mutual inductor are located. In such examples, the tuning capacitor can be coupled to an on-die circuit connected to the center feed.

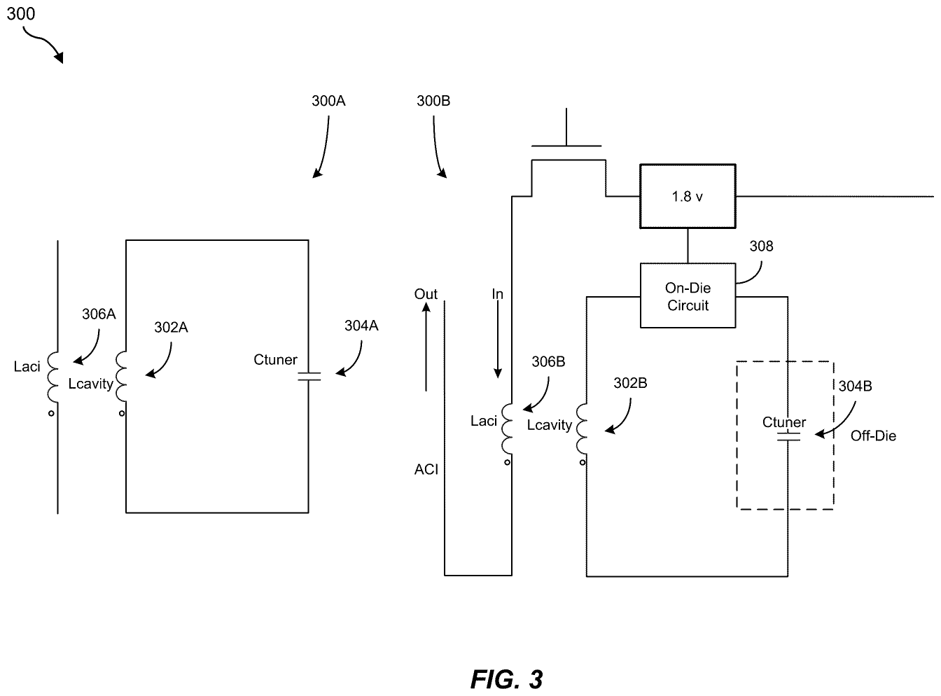

Referring generally to FIGS. 2 and 3, as previously mentioned herein, when using the packaging structure to implement the integrated voltage regulator, the induction value that is produced is limited due to resistance constraints, but the effective inductance can be improved by using mutual inductance. Air core inductor array 200 can have a circular or polygonal shape and a mutual inductor that implements an LC circuit 300, such as LC circuits 300A or 300B. An LC circuit, also called a resonant circuit, tank circuit, or tuned circuit, is an electric circuit including an inductor 302A and 302B, represented by the letter L, and a capacitor 304A and 304B, represented by the letter C, connected together (e.g., in series). The circuit can act as an electrical resonator, an electrical analogue of a tuning fork, storing energy oscillating at the circuit's resonant frequency. When a voltage is applied to the LC circuit, the capacitor is charged and, when the battery supply is cut off, the stored energy from the capacitor is discharged to the inductor. At a resonance frequency, the inductor and the capacitor resonate, thus amplifying the magnetic field. This amplified magnetic field can amplify another magnetic field produced by a proximate air core inductor 306A and 306B through mutual inductance.

Air core inductor array 200 can have a plurality of air core inductors (e.g., in a circular arrangement). An individual air core inductor of array 200 can have an inner column (e.g., of looped wire) corresponding to a first-tier individual inductor 202 and an outer column (e.g., of looped wire) corresponding to a second-tier individual inductor 204, and these individual inductors 202 and 204 can be connected at tops and bottoms thereof by trapezoidal pads 206A and 206B. Thus, an individual air core inductor can be formed of two individual inductors 202 and 204 connected by trapezoidal pads 206A and 206B at tops and bottoms thereof, and the individual air core inductors of array 200 can be isolated from one another.

Addition of a mutual inductor (e.g., LC circuit 300) to air core inductor array 200 can be accomplished by adding a top plate 208 and a bottom plate 210 respectively above and below the air core inductor array 200 in a manner that forms the mutual inductor. For example, a center feed 212 can be provided as a plated through hole surrounded by the air core inductor array 200. Additionally, a via fence 214 can be provided as a plurality of plated through holes surrounding the air core inductor array. In some examples, the via fence can be shorted to both the top plate 208 and the bottom plate 210 and the center feed 212 can be shorted to the one of the plates (e.g., bottom plate 210) but left open at the other end (e.g., top end). A tuning capacitor 304A and 304B can be connected to the open end of the center feed 212 and the top plate 208, thus connecting the center feed 212 to the via fence 214. In some examples, tuning capacitor 304A can be implemented on a same die on which the air core inductor array and a mutual inductor formed of the top plate 208, the bottom plate 210, the center feed 212, and the via fence 214 are located. In such examples, the tuning capacitor 304A can have a switch associated with resistance to tune the capacitor 304A. In other examples, tuning capacitor 304B can be implemented off of the die on which the air core inductor array and a mutual inductor formed of the top plate 208, the bottom plate 210, the center feed 212, and the via fence 214 are located. In such examples, tuning capacitor 304B can connect to an on-die circuit 308 coupled to the open end of the center feed 212. The tuning capacitor 304A and 304B can be adjusted to choose a capacitor value that causes the mutual inductor (e.g., LC circuit 300) to resonate with an inductance cavity (Lcavity) at a switching frequency of the integrated voltage regulator for maximum benefit to the effective inductance of the air core inductor array 200.

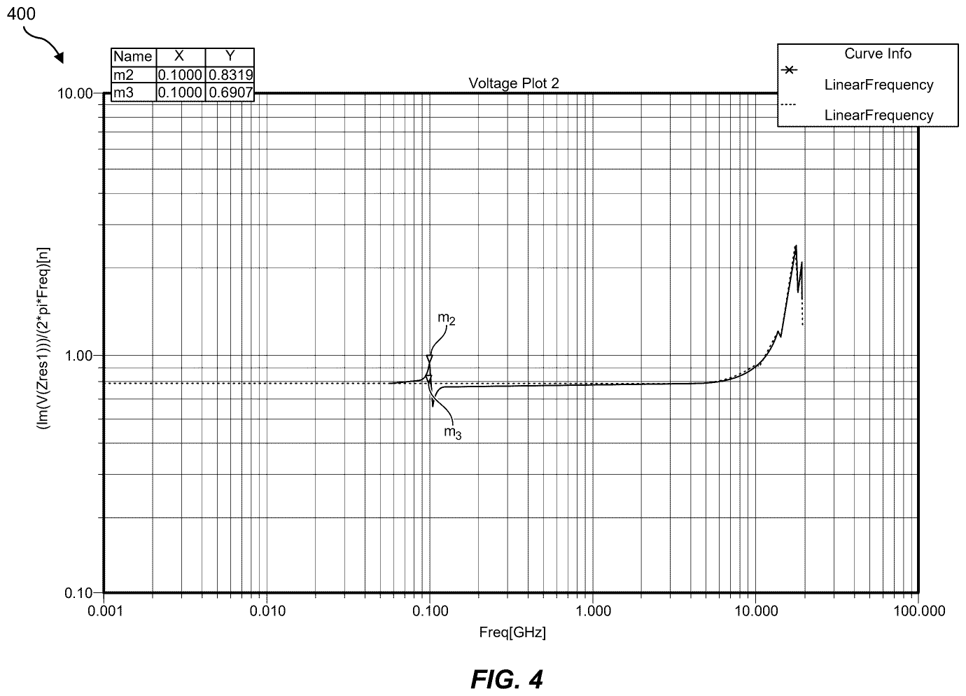

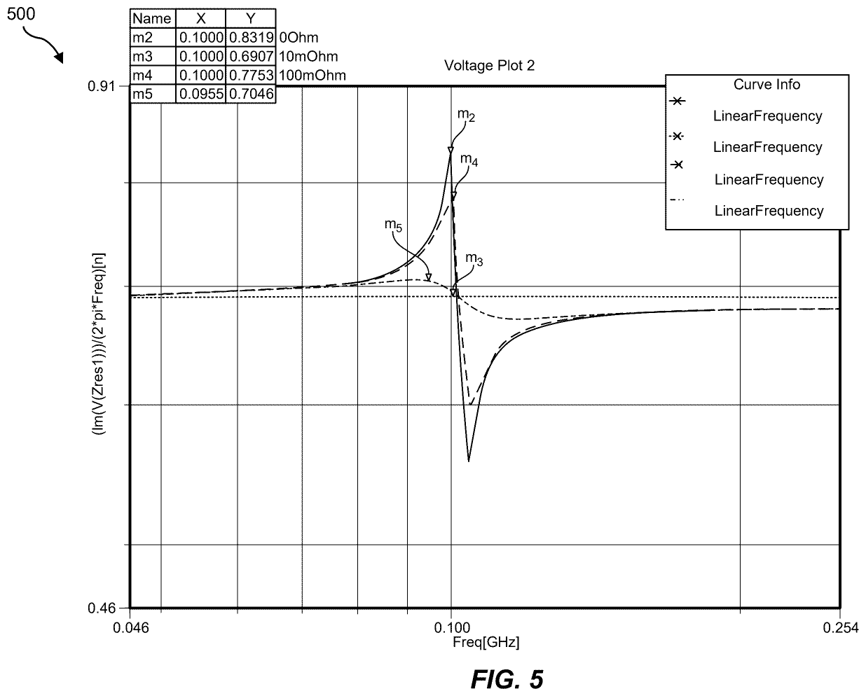

Referring generally to FIGS. 4 and 5, graph 400 demonstrates the benefit of the tuning capacitor in increasing the effective inductance of the air core inductor array. For example, without the tuning capacitor, the effective inductance exhibited by the air core inductor array can be 0.69 nanohenrys (nH). Employing the tuning capacitor can increase the exhibited effective inductance to 0.83 nH. Graph 500 demonstrates results of a sensitivity study ascertaining that parasitic resistance of the LC circuit can negatively impact the improvement achieved by employing the tuning capacitor. Thus, characteristics of the integrated voltage regulator can be selected to control parasitic capacitance of the mutual inductor, including a power grid connection. Controlling the parasitic capacitance of the mutual inductor can include, for example, minimizing the parasitic capacitance, reducing the parasitic capacitance, reducing the parasitic capacitance below a threshold (e.g., ten milli-Ohms per pico-Farad (mOhm/pF)), and/or causing the parasitic capacitance to be within a range (e.g., 1 mOhm/pF to 10 mOhm/pf).

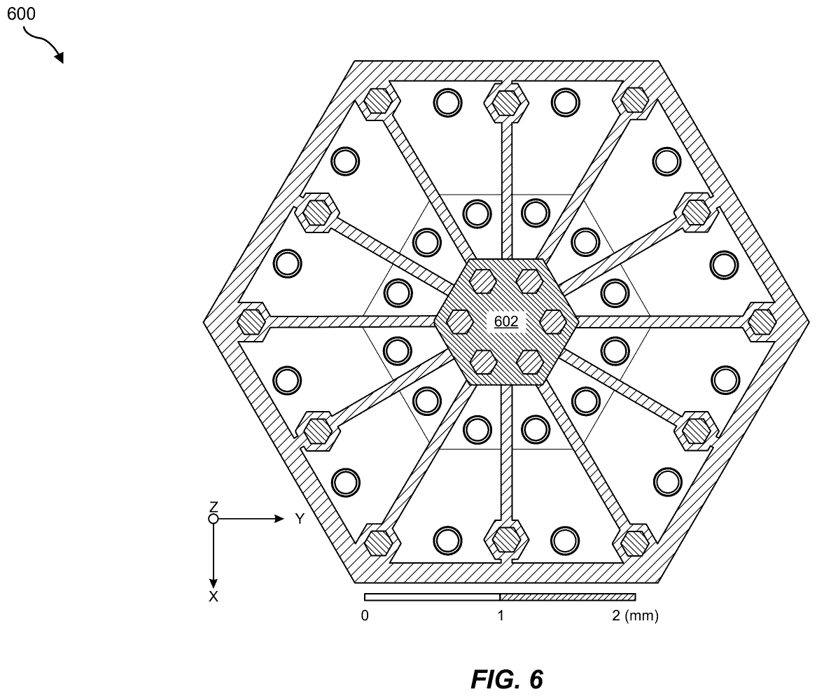

Referring to FIG. 6, an example air core inductor array 600 having a mutual inductor can be implemented with a hexagonal structure that facilitates beehive construction by replicating the hexagonal design for adjacent placement of air core inductor arrays on a die. Such placement can save space on the die while promoting additional mutual inductance between adjacent air core inductor arrays, thus achieving further improvement in the effective inductance of the air core inductor arrays. With this hexagonal structure, the center feed 602 can include multiple plated through holes to increase couplings. Multiple air core inductor arrays 600 placed in this manner can correspond to power field effect transistor (FETs) implemented in a hexagon pattern to form an integrated voltage regulator that can be integrated into an ASIC.

Referring to FIG. 7, graph 700 demonstrates the benefit of the hexagonal structure and beehive construction style placement both with and without tuning capacitor. For example, even without the tuning capacitor, the effective inductance exhibited by the air core inductor array having the hexagonal structure can be 1.35 nanohenrys (nH). Employing the tuning capacitor with this hexagonal structure can increase the exhibited effective inductance to 2.53 nH, which is a significantly higher percentage increase than is observed without employing the hexagonal structure.

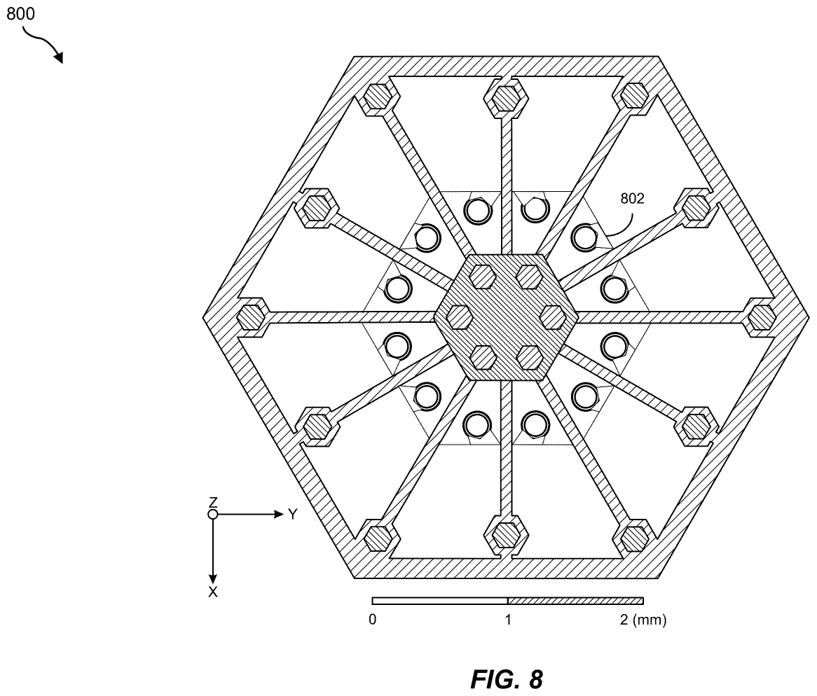

Referring generally to FIGS. 8-10, the mutual inductance of the air core inductor array 800 can be optimized by adjusting (e.g., increasing, decreasing, etc.) the radius 802 of the air core inductor array 800. Adjusting the radius can involve adjusting positions of the individual air core inductors and observing results to the effective inductance of the air core inductor array 800 until an optimal radius is found. Accordingly, the individual air core inductors of array 800 can be repositionable to facilitate experimentation and analysis to produce analysis results as depicted in air core inductor array model 900 and/or graph 1000. For example, air core inductor array model 900 can depict a simulated and/or measured magnetic field strength in three dimensions, and graph 1000 can depict a simulated and/or measured voltage plot. Alternatively or additionally, dimensions of an inductance cavity can be used to determine the radius and/or an initial radius for conducting experimentation and analysis.

As set forth above, a fully integrated voltage regulator (IVR) has been adopted due to the improved response to on die current changes. The switching frequency of the IVR is on the order of a few Hundred MHZ, which makes the implementation of the inductor feasible using packaging structures. Even though it is feasible, having higher inductance for reducing AC loss is desirable in some applications. However, simply increasing the inductance by enlarging the loop structure would also cause an increase in parasitic resistance.

The disclosed air core inductor array (ACI) and/or integrated voltage regulator uses one or more measures that employ mutual inductance to increase effective inductance of one or more air core inductor arrays. AC inductance at a switching frequency of the IVR needs to be sufficiently slow to reduce the ripple current, resulting in AC loss. However, increasing inductance for air core inductors means increasing loop area of the ACI, which can result in a higher DC resistance. One technique to increase the inductance of the ACI array is to use mutual coupling from a nearby inductor. The mutual coefficient is limited and determined by distance between the ACI array and the external inductor. Increasing the mutual coupling can be achieved, for example, by increasing a number of plated through holes and/or increasing current in the external inductor.

Based on the observations described above, a hexagon shape structure is proposed. For example, an ACI array can have twelve individual ACIs that are generally shaped like pie pieces that fit within one side of a hexagon. The advantage of such pie piece shaped individual ACIs is that the DC resistance for the horizontal strips (e.g., pads) can be reduced. Between two adjacent ACIs, plated through holes can be inserted. In the center region, a circular plated through hole array can be formed as a center feed for the external inductor. All the plated through holes for the external inductor can be connected by a plane below and above the ACI array. To increase the current in the external inductor, one method is to form an LC resonator. The resonator can have a resonance frequency at a switching frequency of the IVR. Thus, an external capacitor can be used to form the resonator and control the resonance frequency. As also detailed above, simulations evidence that self-inductance of the ACI array can be more than doubled by implementing the measures described above. The sensitivity of the parasitic equivalent series resistance (ESR) of the tuning capacitor can impact the increase that can be gained for the ACI array.

The use of measures described herein that implement mutual inductance to boost the effective inductance of the ACI results in numerous advantages. For example, the hexagon shaped structure can allow compact placement for multiple instances of ACI arrays. Additionally, the pie piece shaped individual inductor design allows decrease in resistance. Also, the external inductor can be implemented within the ACI array. Further, the coupled resonator boosts the magnetic coupling between the external inductor and the ACI array. Further, radius of the structure can be adjusted for different applications. Finally, excitation of the resonator can be affected by other circuit nodes.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

In some examples, all or a portion of an example system can represent portions of a cloud-computing or network-based environment. Cloud-computing environments can provide various services and applications via the Internet. These cloud-based services (e.g., software as a service, platform as a service, infrastructure as a service, etc.) can be accessible through a web browser or other remote interface. Various functions described herein can be provided through a remote desktop environment or any other cloud-based computing environment.

In various implementations, all or a portion of an example system can facilitate multi-tenancy within a cloud-based computing environment. In other words, the modules described herein can configure a computing system (e.g., a server) to facilitate multi-tenancy for one or more of the functions described herein. For example, one or more of the modules described herein can program a server to enable two or more clients (e.g., customers) to share an application that is running on the server. A server programmed in this manner can share an application, operating system, processing system, and/or storage system among multiple customers (i.e., tenants). One or more of the modules described herein can also partition data and/or configuration information of a multi-tenant application for each customer such that one customer cannot access data and/or configuration information of another customer.

According to various implementations, all or a portion of an example system can be implemented within a virtual environment. For example, the modules and/or data described herein can reside and/or execute within a virtual machine. As used herein, the term “virtual machine” generally refers to any operating system environment that is abstracted from computing hardware by a virtual machine manager (e.g., a hypervisor).

In some examples, all or a portion of an example system can represent portions of a mobile computing environment. Mobile computing environments can be implemented by a wide range of mobile computing devices, including mobile phones, tablet computers, e-book readers, personal digital assistants, wearable computing devices (e.g., computing devices with a head-mounted display, smartwatches, etc.), variations or combinations of one or more of the same, or any other suitable mobile computing devices. In some examples, mobile computing environments can have one or more distinct features, including, for example, reliance on battery power, presenting only one foreground application at any given time, remote management features, touchscreen features, location and movement data (e.g., provided by Global Positioning Systems, gyroscopes, accelerometers, etc.), restricted platforms that restrict modifications to system-level configurations and/or that limit the ability of third-party software to inspect the behavior of other applications, controls to restrict the installation of applications (e.g., to only originate from approved application stores), etc. Various functions described herein can be provided for a mobile computing environment and/or can interact with a mobile computing environment.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An air core inductor array, comprising:
a top plate positioned in a first plane;
a bottom plate positioned in a second plane; and
a plurality of air core inductors arranged between the top plate and the bottom plate, wherein the top plate and the bottom plate form a mutual inductor.

2. The air core inductor array of claim 1, further comprising:
a center feed arranged as at least one plated through hole surrounded by the air core inductor array.

3. The air core inductor array of claim 2, further comprising:
a via fence arranged as a plurality of plated through holes surrounding the air core inductor array, wherein the via fence and the center feed are shorted to at least one of the top plate or the bottom plate.

4. The air core inductor array of claim 3, further comprising:
a tuning capacitor connected to the center feed and the via fence.

5. The air core inductor array of claim 4, wherein the tuning capacitor is located on a same die on which the air core inductor array and the mutual inductor formed of the top plate, the bottom plate, the center feed, and the via fence are located.

6. The air core inductor array of claim 5, further comprising:
a switch connected to tune an equivalent series resistance of the tuning capacitor.

7. The air core inductor array of claim 4, wherein the tuning capacitor is located off of a die on which the air core inductor array and the mutual inductor formed of the top plate, the bottom plate, the center feed, and the via fence are located.

8. The air core inductor array of claim 3, wherein a radius of the air core inductor array is selected to maximize a mutual inductance between the air core inductor array and the mutual inductor formed of the top plate, the bottom plate, the center feed, and the via fence.

9. The air core inductor array of claim 1, wherein the plurality of air core inductors is arranged in a hexagonal structure.

10. An integrated voltage regulator, comprising:
an air core inductor array;
a mutual inductor arranged as a top plate positioned above the air core inductor array, a bottom plate positioned below the air core inductor array, a via fence including a plurality of plated through holes surrounding the air core inductor array, and a center feed arranged as at least one plated through hole surrounded by the air core inductor array, wherein the via fence and the center feed are shorted to at least one of the top plate or the bottom plate; and
a tuning capacitor connected to the center feed and the via fence.

11. The integrated voltage regulator of claim 10, wherein the air core inductor array includes a plurality of air core inductors arranged in a hexagonal structure.

12. The integrated voltage regulator of claim 10, wherein a radius of the air core inductor array is selected to maximize a mutual inductance between the air core inductor array and the mutual inductor.

13. The integrated voltage regulator of claim 10, wherein the tuning capacitor is located on a same die on which the air core inductor array and the mutual inductor.

14. The integrated voltage regulator of claim 10, further comprising:
a switch connected to tune an equivalent series resistance of the tuning capacitor.

15. The integrated voltage regulator of claim 10, wherein the tuning capacitor is located off of a die on which the air core inductor array and the mutual inductor are located.

16. A method, comprising:
determining a radius of an air core inductor array including a plurality of air core inductors, wherein a radius of the air core inductor array is determined to maximize a mutual inductance between the air core inductor array and a mutual inductor;
dividing the air core inductor array into a plurality of segments that each form an air core inductor of the air core inductor array; and
adding a top plate and a bottom plate respectively above and below the plurality of air core inductors in a manner that forms the mutual inductor.

17. The method of claim 16, further comprising:
forming a center feed of the air core inductor array by providing at least one plated through hole surrounded by the air core inductor array, wherein the center feed is shorted to at least one of the top plate or the bottom plate.

18. The method of claim 17, further comprising:
forming a via fence by providing a plurality of plated through holes surrounding the air core inductor array, wherein the via fence is shorted to at least one of the top plate or the bottom plate.

19. The method of claim 18, further comprising:
connecting a tuning capacitor to the center feed and the via fence.

20. The method of claim 16, wherein the plurality of air core inductors is arranged in a hexagonal structure.
